(19) United States
(12) Patent Application Publication
(10) Pub. No.: US 2005/0028858 A1
(43) Pub. Date: Feb. 10, 2005

(54) Thermoelectric module and generator

(76) Inventor: Andrea Rossi, Milano (IT)

Correspondence Address: INTELLECTUAL PROPERTY GROUP;FREDRIKSON & BYRON, P.A., 200 SOUTH SIXTH STREET, SUITE 4000, MINNEAPOLIS, MN, 55402, US

(21) Appl. No.: 10/749,370

(22) Filed: Dec. 31, 2003

Related U.S. Application Data
(63) Continuation-in-part of application No. 10/633,868, filed on Aug. 4, 2003, now abandoned.

(51) Int. Cl. H01L 35/30

(52) U.S. Cl. 136/205

(57) ABSTRACT

The invention relates to a thermoelectric module wherein a metallic conductive plate (1) is coated with a platinum layer (2) and a tellurium (3) layer, or other thermoelectric couples. The utilisation of layers of 1 μm or less reduces the ohmic resistance of the thermoelectric materials and allows the production of flat, cylindrical or otherwise shaped modules.

### CROSS REFERENCE

This application claims priority to U.S. application Ser. No. 10/633,868 titled “Thermoelectric Module and Generator” filed on Aug. 4, 2003.

### FIELD OF THE INVENTION

The invention regards a module for thermoelectric applications and a generator of electric power formed with a plurality of such modules.

### BACKGROUND OF THE INVENTION

It is well known in the art the use of the thermoelectric properties of some materials for generating electric power by means of the Seebeck effect or for cooling electronic components by means of the opposed effect, i.e. the Peltier effect.

For sake of brevity, in this description and in the appended claims reference will be made mainly, where not otherwise specified, to the electric power generation with Seebeck effect; however, what will be stated shall not be intended in a limiting manner and the issues set forth must be considered valid, mutatis mutandis, also for the cooling of electronic components or other utilisations based on the Peltier effect.

There are many technological and scientific publications on this subject to which reference should be made for further information, whereas for sake of clarity in this connection it is worth considering herein U.S. Pat. No. 6,274,802 (Fukuda et al.) and US Patent application No. US2002/0046762 in the name of the same applicant of the present application.

The Fukuda patent discloses a syntherized semiconductor for thermoelectric devices, obtained following the hot compression of powders of bismuth (Bi), tellurium (Te), selenium (Se), and antimony (Sb).

The semiconductor material so obtained is useful to make thermoelectric components of opposed polarity (positive and negative), which are connected in series (and/or in parallel) by means of metallic straps.

The patent application to Rossi claims a module made by a thermoelectric couple built up with oriented crystal structures of bismuth and tellurium salts, doped with selenium for the negative pole and with antimony for the positive pole.

The thermoelectric poles of each module are connected by conductive metallic straps likewise in the previous case.

In these two prior documents, the thermoelectric components have the shape of a parallelepiped with a thickness greater than 1 mm; this generates an ohmic resistance which in both cases is faced by providing oriented crystals of the semi conductor materials, but which cannot be reduced below certain limits, also taking into account the resistance due to the contacts between the semiconductors and the straps connecting the modules of the generator.

Indeed these straps are made of a different material from the thermoelectric elements, so that the discontinuity occurring at their junction determines an additional ohmic resistance.

### BRIEF SUMMARY OF THE INVENTION

The present invention provides a thermoelectric module comprising a pair of semiconductor elements of opposed polarities coupled by conducting metal straps, having such structural and functional features as to obtain improved performance when compared to known modules, regarding either the tension generated and the lower ohmic resistance involved.

This is achieved by a module characterized in that one of the conductive metal straps has a portion coated with a first thermoelectric material, and another portion coated with a second thermoelectric material of polarity opposed to the first one.

The layers coated upon the strap have a thickness less than 1 μm (0.001 millimetres) and preferably in the order of 0.1 μm (0.0001 millimetres); among the materials used for the thermoelectric layers there are the couple platinum-selenium and aluminium-selenium, but the preferred couple is platinum-tellurium, while the conductive strap is made of copper, aluminum or any other good electric conductor.

The module so obtained can be piled up or connected in series with other similar modules by means of further conductive straps, thereby forming an electric power generator.

These and further characterising features of the invention are detailed in the description set forth hereafter, regarding a preferred but not exclusive embodiment thereof, shown in the drawings enclosed wherein:

### BRIEF DESCRIPTION OF THE DRAWINGS

FIG. 1 shows a strap coated with thermoelectric materials, according to an embodiment of the present invention;

FIG. 2 shows thermoelectric modules connected in series according to an embodiment of the present invention;

FIG. 3 shows thermoelectric modules like those in FIG. 2, with upper and lower faces respectively cooled and heated;

FIG. 4 shows a generator made with thermoelectric modules in an stacked configuration according to an embodiment of the present invention;

FIG. 5 is a diagram showing the tension variations as a function of the temperature, obtained with thermoelectric modules according to the invention;

FIG. 6 is a longitudinal section of another generator made with thermoelectric modules according to an embodiment of the present invention;

FIG. 7 is a cross section along line VII-VII of FIG. 6;

FIG. 8 is a cross section of a variant of the generator in FIG. 7.

### DETAILED DESCRIPTION OF THE ILLUSTRATED EMBODIMENTS

In the first of these figures numeral 1 indicates a copper strap shaped as a parallelepiped, 20 mm long, 10 mm, wide and 7 mm thick.

Half of the upper face of the strap 1 is coated with a layer of platinum 2, while the other half is coated with a layer of tellurium 3; such layers, which have a thickness less than 1 μm and preferably of 0.1 μm, are obtained from evaporation in a high vacuum environment of the respective metals having 99.99% purity rate.

Nevertheless, any other technology (e.g. sputtering) suitable for applying similar layers of Pt or Te may be used.

The thermoelectric module including the strap 4 with the layers 2, 3, is completed by another copper strap 4 (FIGS. 2, 3) equal to the first one, but without coating layers.

For providing the serial connection of thermoelectric modules according to the invention, the second strap 4 is put upon the first one in a staggered condition, as shown in FIG. 2, covering one of the two layers 2 and 3; the straps 1 and 4 are then kept together by means of springs 7. Obviously springs 7 can be replaced by other means (for instance bands) suitable to hold together the straps firmly for achieving a good electrical contact between the juxtaposed surfaces, without damaging the thin layers 2 and 3.

It is for this reason that mechanical systems are preferred for fastening the straps than those based on weldings, which can damage the aforesaid layers because of the high temperatures involved.

To generate electric power, the thermoelectric modules connected in series have the two faces put at different temperatures; so, for example, in FIG. 2 the inferior faces of the straps 1 are cooled by a liquid flowing in a hollow space 10, adjacent to them.

Generally, the hot face of the modules should be at a temperature higher than 35-40° C., while the cold face should be at a lower temperature of about 15-20° C.

Of course the difference in temperature between the faces of the modules may be larger than this and obtained with many other solutions, depending on the different uses of the present invention and the electric power to be generated.

For example it will be possible to take advantage of the waste heat released from hot walls such as those of furnaces, internal combustion engines or others, and of those heated by the sun (reference could be made to solar panels or similar); as an alternative, the heat may be supplied by flames or electric heaters and the like.

Another possible constructive solution is shown in FIG. 3, wherein the upper face of the modules is cooled by the coil 13 of the vaporizator of a refrigerating apparatus, while the other face is heated by the condenser 14 of the same apparatus.

This solution makes it possible to recover energy from a motor intended for other purposes, e.g. for automotive use, which drives the compressor of the refrigerating apparatus by means of a transmission belt or similar.

From the functioning point of view, the thermoelectric module of this invention allows the generation of electric power (by Seebeck effect) or the cooling of electronic components (by Peltier effect) with a much higher efficiency than in the state of the art.

Indeed, the ultra thin layers 2, 3 of the thermocouples reduce by orders of magnitude their ohmic resistance; this effect is further enhanced by the wide surface, versus the thickness, of the layers. Furthermore, the latter are applied upon the substratum formed by the strap 1, in a way which allows a close junction therewith, thereby eliminating any contact ohmic resistances due to discontinuity.

On this subject it is of note to point out that in the prior references considered above, it is not explained how the elements of the thermocouples are fixed to the straps; nevertheless, if such fixing were obtained by means of welding, the melted region of the thermoelectric material would be somehow physically altered (reference should be made here to the fact that in both documents cited, the orientation of the crystals in thermoelectric couples is critical).

Last it is of note to add that unexpected good results have been reached with modules wherein the material for one of the thermoelectric layers is platinum, particularly when it is used in combination with tellurium for the other layer.

Indeed this couple has proved to maintain a high performance stability in the time.

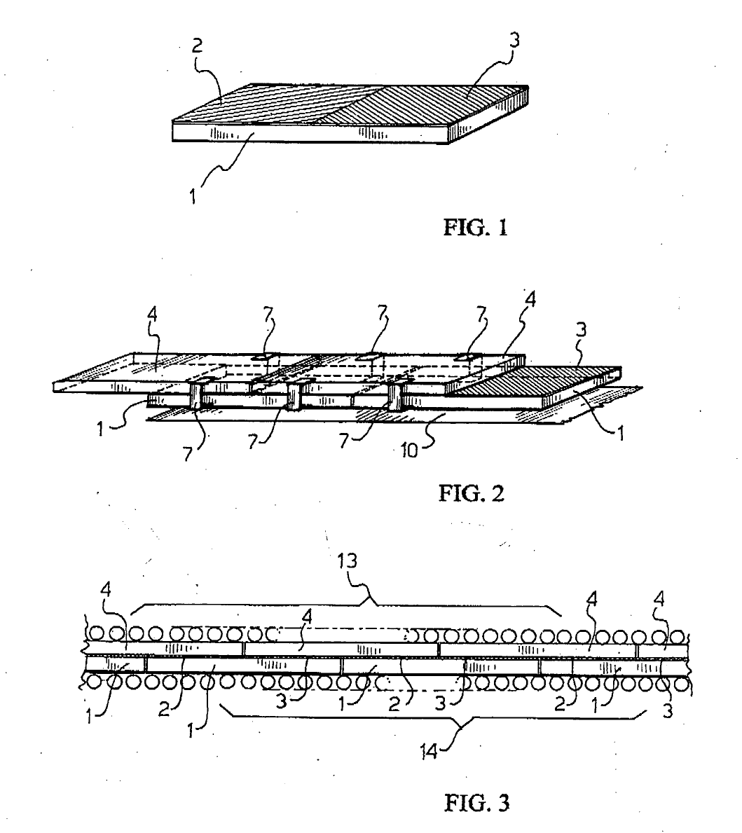

The efficiency of the thermocouple platinum-tellurium is shown in diagram 5, reporting the yield (in millivolts) as a function of the difference of temperature between the hot and the cold faces of ten thermoelectric modules, with straps having the same dimensions as that of the strap in FIG. 1, connected in series as explained above.

In this respect it is important to emphasize that even if the platinum is very expensive, the use of ultra thin layers as above described, makes the industrial application of this invention economically competitive.

Of course, the latter may be subject to variations with respect to the embodiment herein considered.

First of all it should be pointed out that although there have been shown modules with flat shape (the straps 3, 4 are parallelepiped), they could also be made with a cylindrical geometry; reference should be made to the case of modules connected in series, as seen before in FIG. 2, but with a circular layout applied upon a cylindrical surface like, for example, that of a hot pipe, for generating power exploiting the heat of fumes or of another fluid flowing therein, which would be otherwise wasted.

This result has been rendered possible by the ultra thin thermoelectric layers, which can be applied even upon non-flat substrata contrary to what occurs for the semiconductors of parallelepiped shape of the prior art.

In other words the use of layers of 1 μm or less allows the efficient application (by means of vacuum vaporization, sputtering or other), of thermoelectric materials even upon surfaces not flat, without obstacle or loss of efficiency.

Also for what it concerns the thermoelectric materials there can be changes with respect to the couple platinum-tellurium.

For example the couple platinum-nickel, further to generating electric power, showed an unexpected catalyzing effect on the exhaust of diesel combustion engines.

Indeed, Pt—Ni modules according to the invention were tested on the exhaust of diesel engines and proved themselves efficacious as catalyzers for the depurating exhaust.

Among the couples which gave good yield in producing electric power, mention can be made to platinum-selenium, selenium-aluminium, and nickel/chrome alloys (doped with C, Si, Fe)-nickel/copper alloys (doped with C, Si, Mn, Cr, Fe, S).

The following tables 1, 2, 3 report the voltages obtained with 10 modules as described above, utilizing different couples of thermoelectric materials (the p between brackets indicates the positive pole, whereas n stands for the negative one).

In the tables the first two columns indicate respectively the temperature in ° C. of the cold and of the hot side of the modules, while the third and fourth columns report the voltage (in mV) measured respectively for modules connected in series as in FIG. 2, and modules stacked as it will be better described later.

TABLE 1
Couple Platinum (p)-Tellurium (n)

| Temperature | Temperature | Voltage | Voltage |
|---|---|---|---|
| Cold side | Hot side | Modules in series | Modules stacked |
| 20 | 30 | 5 | 2 |
| 20 | 40 | 10 | 4 |
| 20 | 50 | 16 | 7 |
| 20 | 60 | 21 | 10 |
| 20 | 70 | 26 | 12 |
| 20 | 80 | 32 | 15 |
| 20 | 90 | 37 | 18 |
| 20 | 100 | 42 | 20 |

TABLE 2
Couple Selenium (p)-Aluminium (n)

| Temperature | Temperature | Voltage | Voltage |
|---|---|---|---|
| Cold side | Hot side | Modules in series | Modules stacked |
| 20 | 30 | 6 | 2 |
| 20 | 40 | 12 | 5 |
| 20 | 50 | 18 | 8 |
| 20 | 60 | 22 | 10 |
| 20 | 70 | 28 | 13 |
| 20 | 80 | 33 | 16 |
| 20 | 90 | 39 | 19 |
| 20 | 100 | 45 | 22 |

TABLE 3
Couple NiCr alloy (p, doped with C, Si, Fe) - NiCu alloy
(n, doped with C, Si, Mn, Cr, Fe, S)

| Temperature | Temperature | Voltage | Voltage |
|---|---|---|---|
| Cold side | Hot side | Modules in series | Modules stacked |
| 20 | 30 | 2 | 1 |
| 20 | 40 | 4 | 2 |
| 20 | 50 | 8 | 3 |
| 20 | 60 | 11 | 4 |
| 20 | 70 | 14 | 6 |
| 20 | 80 | 17 | 8 |
| 20 | 90 | 20 | 9 |
| 20 | 100 | 22 | 10 |

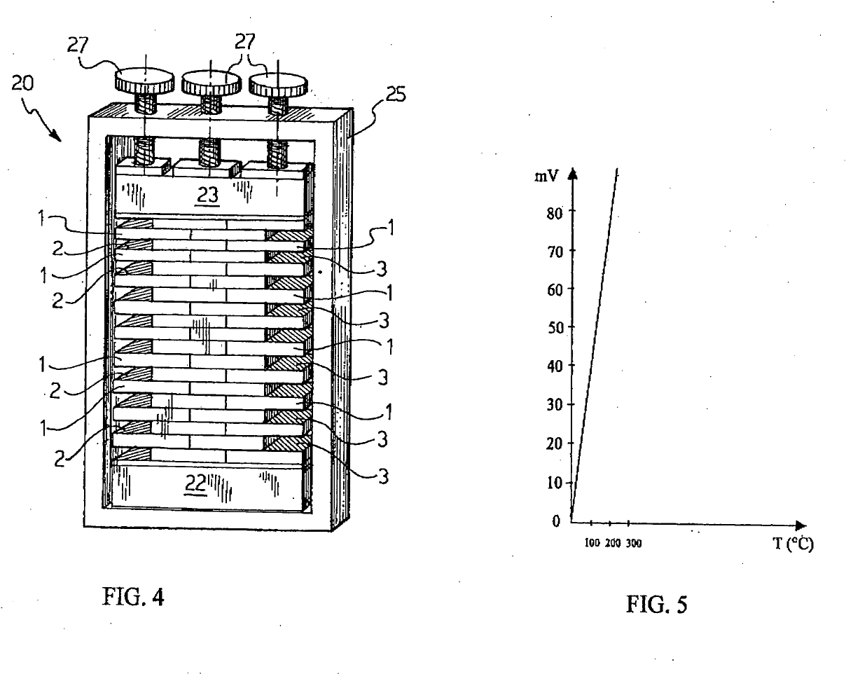

Turning now to consider the piles of thermoelectric modules, reference should be made to FIG. 4 wherein it is shown a generator 20 made by stacks of straps 1 coated with layers 2, 3 according to the embodiment of FIG. 1; in the piles the straps 4 without thermoelectric layers are not present anymore and the connection between the modules is provided by the coated straps 1.

As can be seen, according to this embodiment the straps are offset thereby protruding from the edge; this allows a temperature difference to form between the upper and the lower faces, for example by convection utilising cold or hot air jets, or by means of one of the cooling (or heating) system described above.

For example it could be envisaged to place the coils of the evaporator and of the condenser of a refrigerating apparatus, on the surfaces of straps 1 protruding from the sides of the generator in FIG. 4.

The protruding ends of the straps can be insulated from each other in a known manner, for instance by means of ceramic material or silicon oxide (SIO).

The piles of straps 1 rest upon a bar 22 of copper and a similar bar 23 is put at their upper end. The generator 20 includes an outer supporting structure 25 having the shape of a frame and made with insulating material (such as plastics or others); in the upper part of this structure there are screwed shanks 27 which, once they are screwed, press the piles of thermoelectric straps urging on the upper bar 23.

With this embodiment of the invention there have been obtained good results and for the sake of brevity, reference can be made to the explanations given before.

It is of note that equivalent generators can be obtained by increasing the number of piles arranged side by side, or also by using only one pile.

Moreover, it is possible to make generators wherein the straps are stacked in a regular manner one upon the other (i.e. not offset), and further ones which make use of heating or cooling means arranged upon and under the piles instead of the copper bars 22, 23, which in these cases would be placed along the sides of the piles.

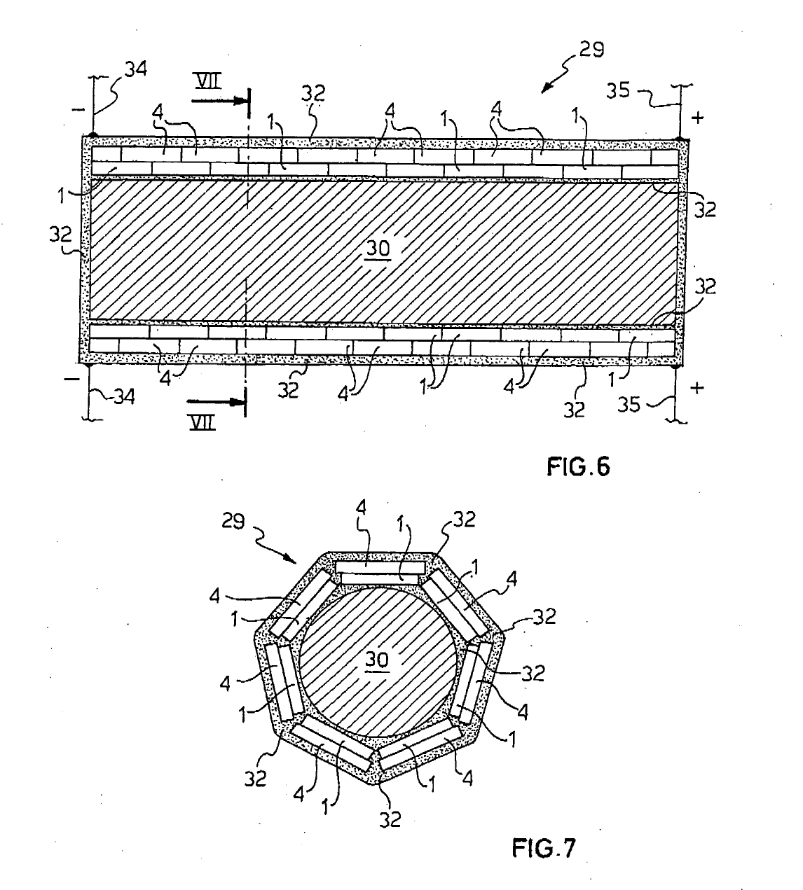

Last, with reference to what has been set forth at the beginning of this description, it is noted that further to the electric power generation, the thermoelectric modules of this invention are suitable also for cooling electronic components or for use in other applications based on the Peltier effect. Finally a further important application of the thermoelectric modules according to the present invention is shown in FIGS. 6, 7 and 8, wherein the elements already referred to in the previous examples have been indicated by the same numerals.

This further application is a new process for recovering energy from spent nuclear fuel.

Indeed, as is known the nuclear plants for production of energy originate a large amount of nuclear wastes (in the order of thousands of tons around the world) formed by uranium or plutonium rods, which are not radioactive enough to power a nuclear reactor but still irradiate heat and can reach temperatures of about 600° C. and even more.

These conditions decay through a long period of time, so that according to the new process it is possible to recover energy from nuclear waste by applying them on the thermoelectric modules of the present invention; an example of a generator 29 so obtained, is shown in FIGS. 6, 7.

As can be seen, a spent uranium rod 30 having a circular cross section is covered by a plurality of modules connected in series like in the embodiment of FIG. 2: in this case the straps 1 with the thin layers 2 and 3 of thermoelectric material (i.e. Pt—Te or any of the other couples already referred to above) are applied on the outer surface of rod 30 and are electrically connected in series by straps 4 of conductive metal, superposed in a staggered condition.

Since straps 1 are of parallelepiped shape, they are arranged tangentially with respect to the rod 30 and are attached thereto by means of a cement 32, thermally conductive and electrically insulating.

In the illustrated embodiment this cement is the Sauersen Electric Cement N. 78, commercially available and distributed in Italy by a company called Eurorefrattari.

This product can be sprayed and is normally used for electrical applications such as alternators and other electric machines; it is resistant at temperatures up to 1538° C., it has a tensile strength of about 22.8 Kg/cm² and a compression strength around 232 Kg/cm², whereas its dielectric strength at 750° C. is 500 V/mm and the electric resistivity is at 750° C. is of 10⁹ Ohm×cm.

Of course, any other cement having technical features suitable for the described use can be employed instead of the Sauersen N. 78.

The cement 32 is also poured upon the outer surface of the thermoelectric modules and on the ends of rod 30, thereby providing a wrapping of the generator 29, from which only electric wires 34, 35 connected to the modules come out.

For generating electric current the generator 29 is immersed in a pool of water (not shown in the drawings) of the type in which there are usually maintained the radioactive nuclear waste, so that the straps 1 and 4 are kept at different temperature.

Indeed straps 1 are hot (even in the order of hundreds of ° C.) because they are heated by the spent uranium rod 30, whereas the straps 4 are cooled by the water of the pool which is at ambient temperature or in any case at a temperature below the boiling point of the water.

This difference of temperature allows the production of electric power by means of Seebeck effect, as already explained above.

It must however be emphasized that in this case such a result is achieved by exploiting the heat produced by rods of spent nuclear fuel, thereby providing for an important and useful recovery of energy which otherwise would be lost.

It should be further considered that variants are possible for this embodiment of the invention.

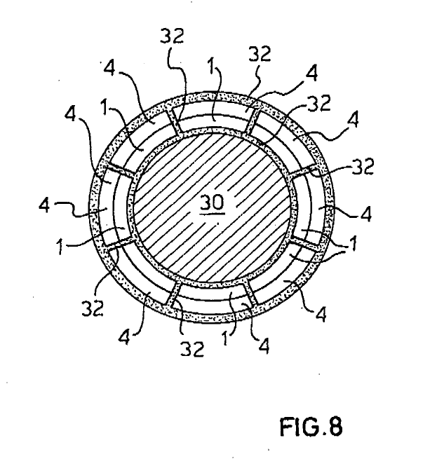

For instance, as already stated above, the shape of the straps 1 and 4 might be different from that parallelepiped; a possible alternative is shown in FIG. 8 which is a cross sectional view of a generator similar to that of FIG. 7.

In this case the cross sections of the straps 1 and 4 have the shape of ring sectors coaxial with the rod 30; the straps are applied on the latter by means of cement 32 which is also poured on the outer surface of the straps 4, likewise in the previous embodiment.

Moreover, the cement 32 also radially insulates the straps 1 and 4 which are longitudinally arranged in rows along the rod 30, so as to be connected in series like shown in FIG. 6.

It should be emphasised that in either cases of FIGS. 7 and 8, the rows of straps 1 and 4 may be connected with each other in series or in parallel, depending on the voltage and the electric power to be obtained.

As a further variant of the invention, it should be taken into account the possibility of providing a generator using a plurality of rods (instead of the single one above) arranged side by side and thereby forming a sort of bed, on which there are applied the straps 1 and 4 in accordance with what has been explained heretofore.

All of these alternative embodiments are encompassed by the scope of the following claims.

1. Thermoelectric module, comprising: a plurality of thermoelectric materials with opposed polarity connected by a first and a second conductive element wherein such thermoelectric materials are configured according to respective coating layers applied on at least one of the conductive elements.

2. The module according to claim 1, wherein said coating layers have a thickness equal or less than 1 μm.

3. The module according to claim 2, wherein said coating layers have a thickness of about 0.1 μm.

4. The module according to claim 3, wherein said coating layers coat respective surface portions of the conductive element, having substantially the same area.

5. The module according to claim 1, wherein said coating layers are respectively made of platinum and tellurium.

6. The module according to claim 1, wherein said coating layers are respectively made of platinum and selenium.

7. The module according to claim 1, wherein said coating layers are respectively made of platinum and nickel thereby providing, further to a thermoelectric effect, also a catalyzer effect on the exhaust of internal combustion engines.

8. The module according to claim 1, wherein said coating layers are respectively made with a Ni—Cr alloy doped with C, Si, Fe, and a Ni—Cu alloy doped with C, Si, Mn, Cr, Fe, S.

9. The module according to claim 1, wherein said conductive elements are straps made of copper, aluminium or other conductive metal, and wherein the coating layers coat one face of the relative strap.

10. The module according to claim 9, wherein the straps are kept pressed one against the other thereby providing a good contact between at least one of the coating layers and the other strap.

11. The module according to claim 9, wherein the straps have the shape of a parallelepiped.

12. The module according to claim 9, wherein the strap has a thickness less than 10 mm.

13. A thermoelectric generator, comprising: a plurality of modules which include a first conductive strap with a face coated by layers of thermoelectric material having opposed polarity, and a second conductive strap for the electrical connection of such layers, wherein the second strap is juxtaposed to the first strap so as to connect one of the thermoelectric layers thereof with the layer of opposed polarity of an adjacent strap, thereby connecting in series the respective modules.

14. The generator according to claim 13, wherein the second strap is not coated with thermoelectric layers.

15. Generator according to claim 13, further comprising means for heating and/or cooling the straps

16. Generator according to claim 15, wherein the means for heating and cooling the straps comprises respectively the condenser and the evaporator of a refrigerating apparatus.

17. A thermoelectric generator comprising a plurality of conductive straps which have a face coated with thermoelectric layers of opposed polarity, stacked one upon the other.

18. The generator according to claim 16, wherein the straps are stacked in an offset condition with their ends protruding from sides of the piles.

19. The generator according to claim 17, comprising means for heating and/or cooling the straps.

20. Generator according to claim 19, wherein the means for heating and cooling the straps comprises respectively the condenser and the evaporator of a refrigerating apparatus.

21. A thermoelectric generator, comprising: a plurality of modules which include a first conductive strap with a face coated by layers of thermoelectric material having opposed polarity, and a second conductive strap for the electric connection of such layers, wherein the second strap is juxtaposed to the first strap so as to connect one of the thermoelectric layers thereof with the layer of opposed polarity of an adjacent strap, thereby connecting in series the respective modules, wherein said modules are applied on a rod of spent nuclear fuel.

22. The generator according to claim 21, wherein the straps are applied on the rod of spent nuclear fuel by means of a cement electrically insulating and thermally conductive.

23. The generator according to claim 22, wherein the rod with the modules applied thereon is wrapped in an impermeable wrapping from which electric wires come out.

24. The generator according to claim 23, wherein the wrapping is made from said cement poured onto the outer surface of the thermoelectric modules and the ends of the nuclear rod.

25. The generator according to claim 23, wherein the rod with the modules and the wrapping applied thereon, is immersed in water.

26. The generator according to claim 24, wherein the cement is Sauersen Electric Cement N. 78.

27. The generator according to claim 21, wherein the straps have a parallelepiped shape and are tangentially applied on the rod.

28. The generator according to claim 21, wherein the cross sections of the straps have the shape of ring sectors coaxial with the rod on which they are applied.
